(19) United States
(12) Patent Application Publication
(10) Pub. No.: US 2025/0226201 A1
(43) Pub. Date: Jul. 10, 2025

(54) SEMICONDUCTOR PROCESSING METHOD

(71) Applicant: GlobalWafers Co., Ltd., Hsinchu (TW)

(72) Inventor: Ching-Shan Lin, Hsinchu (TW)

(73) Assignee: GlobalWafers Co., Ltd., Hsinchu (TW)

(21) Appl. No.: 18/928,189

(22) Filed: Oct. 28, 2024

Related U.S. Application Data
(60) Provisional application No. 63/619,316, filed on Jan. 10, 2024.

(51) Int. Cl. H01L 21/02; B28D 1/22

(52) U.S. Cl. CPC H01L 21/02013; B28D 1/22

(57) ABSTRACT

A semiconductor processing method includes the following steps. A semiconductor ingot is cut to obtain a semiconductor wafer, in which the semiconductor wafer includes a first side and a second side opposite to the first side. A double-sided grinding process is performed to simultaneously grind the first side and the second side of the semiconductor wafer using diamond grinding fluid. The diamond grinding fluid contains diamond particles with a median particle diameter of 0.1 μm to 3 μm.

### CROSS-REFERENCE TO RELATED APPLICATION

This application claims the priority benefit of U.S. application Ser. No. 63/619,316, filed on Jan. 10, 2024. The entirety of the above-mentioned patent application is hereby incorporated by reference herein and made a part of this specification.

### BACKGROUND

### Technical Field

The disclosure relates to a semiconductor processing method, and particularly relates to a method of grinding a semiconductor wafer.

### Description of Related Art

The semiconductor wafer is widely used and serves as the core material for manufacturing various chips. During the chip manufacturing process, the surface of the semiconductor wafer typically needs to be ground and polished to ensure that subsequent semiconductor processes can be performed out on a flat surface. Generally speaking, the grinding process is divided into three stages: coarse grinding, medium grinding, and fine grinding, to ensure the uniformity of wafer thickness. After grinding is completed, rough polishing and fine polishing are required to further reduce the roughness of the wafer surface. However, this series of grinding and polishing processes is both time-consuming and costly.

### SUMMARY

The disclosure provides a semiconductor processing method that can reduce the time and cost required for grinding and polishing processes.

At least one embodiment of the disclosure provides a semiconductor processing method, including the following steps. A semiconductor ingot is cut to obtain a semiconductor wafer, in which the semiconductor wafer includes a first side and a second side opposite to the first side. A double-sided grinding process is performed to simultaneously grind the first side and the second side of the semiconductor wafer using diamond grinding fluid. The diamond grinding fluid contains diamond particles with a median particle diameter of 0.1 μm to 3 μm.

### BRIEF DESCRIPTION OF THE DRAWINGS

FIG. 1A to FIG. 1D are various schematic diagrams of a semiconductor processing method according to embodiments of the disclosure.

FIG. 2 is a flow chart of the semiconductor processing method according to an embodiment of the disclosure.

### DESCRIPTION OF THE EMBODIMENTS

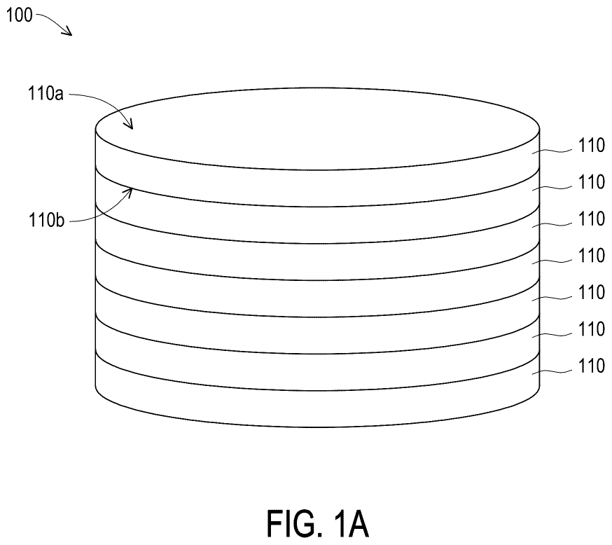

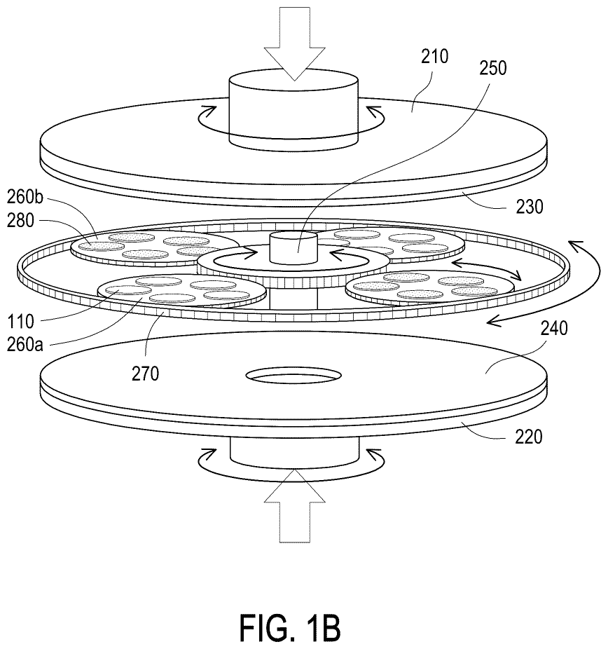

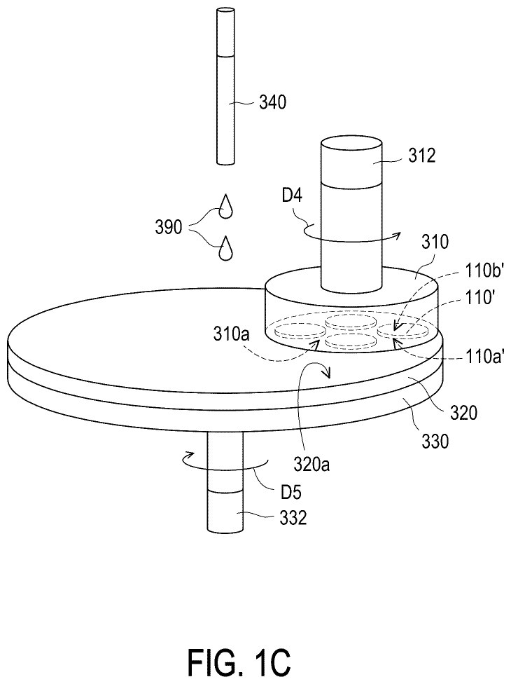

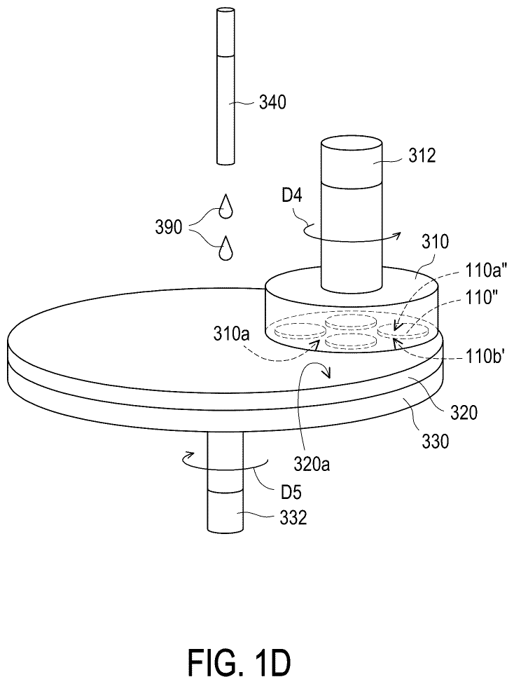

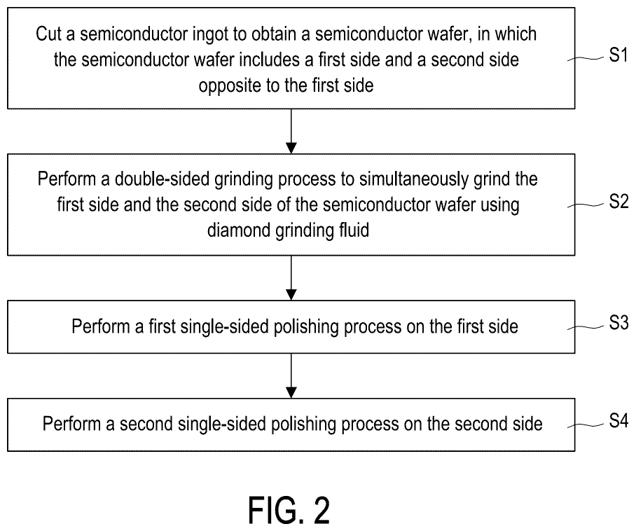

FIG. 1A to FIG. 1D are various schematic diagrams of a semiconductor processing method according to embodiments of the disclosure. FIG. 2 is a flow chart of the semiconductor processing method according to an embodiment of the disclosure. Referring to FIG. 1A and Step S1 in FIG. 2, a semiconductor ingot 100 is cut to obtain the semiconductor wafer 110. In some embodiments, the semiconductor ingot 100 includes, for example, elemental semiconductors (such as silicon, germanium, or other suitable materials), compound semiconductors (such as silicon carbide, gallium arsenide, gallium phosphide, indium phosphide, indium arsenide, indium antimonide, or other suitable materials), alloy semiconductors (such as SiGe, GaAsP, AlInAs, AlGaAs, GaInAs, GaInP, GaInAsP, or other suitable materials), or other types of semiconductor materials.

In some embodiments, each semiconductor wafer 110 includes a first side 110a and a second side 110b opposite to the first side 110a. At this stage, the first side 110a and the second side 110b of the semiconductor wafer 110 are both preliminary polished surfaces and still have some roughness. For example, a surface roughness Ra of the first side 110a and the second side 110b is 1000 nm to 5000 nm. Furthermore, at this stage, the semiconductor wafer 110 has a BOW of +80 μm to −80 μm, and a WARP of 0 μm to 80 μm. In some embodiments, the semiconductor wafer 110 includes silicon carbide, and one of the first side 110a and the second side 110b is a silicon side and the other is a carbon side. In some embodiments, the semiconductor wafer 110 is a wafer of 6 to 8 inches.

In some embodiments, the semiconductor wafer 110 has a thickness of 200 μm to 1600 μm.

Next, referring to FIG. 1B and Step S2 in FIG. 2, a double-sided grinding process is performed on the semiconductor wafer 110. In this embodiment, the semiconductor wafer 110 is placed in a double-sided grinding device, and the first side 110a and the second side 110b are simultaneously grinded. The double-sided grinding device includes a first grinding disc 210, a second grinding disc 220, a first grinding pad 230, a second grinding pad 240, a sun gear 250, a first carrier 260a, a second carrier 260b, an inner gear 270, and an adjust structure 280.

The first grinding disc 210 and the second grinding disc 220 are disposed oppositely. The first grinding pad 230 and the second grinding pad 240 are respectively disposed on the first grinding disc 210 and the second grinding disc 220, and are sandwiched between the first grinding disc 210 and the second grinding disc 220. The sun gear 250, the first carrier 260a, the second carrier 260b, and the inner gear 270 are positioned between the first grinding pad 230 and the second grinding pad 240. When performing the double-sided grinding process, the first grinding disc 210 and the second grinding disc 220 rotate in opposite directions.

The first carrier 260a and the second carrier 260b have gears on the periphery thereof, and are meshed between the inner gear 270 and the sun gear 250, allowing the first carrier 260a and the second carrier 260b to not only revolve around the sun gear 250 but also rotate on their own.

The first carrier 260a has through holes for accommodating a plurality of semiconductor wafers 110, and the plurality of semiconductor wafers 110 are fixed in the through holes of the first carrier 260. In other words, the double-sided grinding process may be performed on multiple semiconductor wafers 110 at the same time. In some embodiments, the semiconductor wafers 110 may be obtained by cutting one or more semiconductor ingots. Optionally, the second carrier 260b has a plurality of through holes for accommodating the adjust structure 280, and the adjust structure 280 is fixed in the through holes of the second carrier 260b to adjust the process. In some embodiments, the combination of the second carrier 260b and the adjust structure 280 may also be replaced by an adjustment ring, and the adjustment ring is directly meshed between the inner gear 270 and the sun gear 250. When performing the double-sided grinding process, the inner gear 270 and the sun gear 250 drive the first carrier 260a and the second carrier 260b to rotate.

In this embodiment, when performing the double-sided grinding process, diamond grinding fluid is applied to the first side and the second side of the semiconductor wafer 110 to simultaneously grind the first side and the second side using the diamond grinding fluid. The diamond grinding fluid contains abrasives and a carrier solution, in which the abrasives contain diamond particles with a median particle diameter (D50) of 0.1 μm to 3 μm, and the carrier solution contains water, alcohol, a combination of the above, or other solutions.

In some embodiments, when performing the double-sided grinding process, 1 to 10 (take 5 in the drawing as an example) semiconductor wafers 110 are disposed in each first carrier 260a, and weight is applied to the semiconductor wafers 110 in the first carrier 260a. In some embodiments, the thickness of the semiconductor wafer 110 is reduced by 20 μm to 28 μm in the double-sided grinding process. In some embodiments, weight is applied to the semiconductor wafers 110 in the multiple first carriers 260a simultaneously. For example, a load of 100 kg to 200 kg is applied to the semiconductor wafers 110 in 1 to 5 first carriers 260a. Each first carrier 260a includes, for example, one 8-inch semiconductor wafer 110 or five 6-inch semiconductor wafers 110.

In some embodiments, the semiconductor wafer 110 undergoes the double-sided grinding process to form a semiconductor wafer 110′ including a first side 110a′ and a second side 110b′ (reference may be made to FIG. 1B and FIG. 1C), in which the surface roughness Ra of 110a′ and the second side 110b′ is 1.0 nm to 5.0 nm. In addition, after performing the double-sided grinding process, the BOW of the semiconductor wafer 110 is +50 μm to −50 μm, and the WARP is 0 μm to 50 μm.

In an embodiment of the disclosure, a one-time double-sided grinding process is used to replace the complicated process from coarse grinding to fine grinding, thereby greatly saving the time and cost required for processing. The double-sided grinding process is used to simultaneously grind both sides of the semiconductor wafer 110. When both sides reach balanced roughness at the same time, the BOW and WARP can be improved; on the contrary, if two single-sided grinding processes are used to grind the two sides of the semiconductor wafer 110 separately, it is easy to cause the surface roughness of the two sides of the semiconductor wafer 110 to be inconsistent after processing, causing abnormal processing problems, and obtaining poor BOW and WARP.

Next, referring to FIG. 1C and Step S3 in FIG. 2. After performing the double-sided grinding process, a first single-sided polishing process is performed on the first side. In this embodiment, the semiconductor wafer 110′ is placed in a single-sided polishing device, and a polishing process is performed on the first side 110a′. The single-sided polishing device includes a polishing carrier 310, an actuator 312, a polishing pad 320, a turntable 330, an actuator 332, and a polishing liquid supply unit 340.

The polishing carrier 310 is suitable for fixing one or more semiconductor wafers 110′. The turntable 330 is disposed at a corresponding position of the polishing carrier 310 for supporting the polishing pad 320. When polishing the semiconductor wafer 110′, a surface 320a of the polishing pad 320 is adapted to face the semiconductor wafer 110′ and a surface 310a of the polishing carrier 310.

The actuator 312 drives the whole or part of the polishing carrier 310 to move or rotate along the corresponding direction. In some embodiments, the actuator 312 may include a power supply device, a motor, a belt, a gear, and other related components, but the disclosure is not limited thereto. In addition, related components such as communication components, power components, shock-absorbing components, positioning components, or sensing components, may also be included in the actuator 312, but the disclosure is not limited thereto.

The actuator 332 drives the turntable 330 and/or the polishing pad 320 thereon to rotate along the corresponding direction. In some embodiments, the rotational direction of the actuator 312 (for example, a fourth direction D4) and the rotational direction of the actuator 332 (for example, a fifth direction D5) may be the same or different.

The polishing liquid supply unit 340 may provide polishing liquid 390 to the semiconductor wafer 110′ in the single-sided polishing process to polish the semiconductor wafer 110′. In some embodiments, the polishing fluid 390 includes abrasives, dispersants, water, and lubricants.

In some embodiments, the thickness of the semiconductor wafer 110′ is reduced by 1 μm to 2 μm in the first single-sided polishing process. In some embodiments, the first side 110a′ of the semiconductor wafer 110′ is subjected to the first single-sided polishing process to form a semiconductor wafer 110″ including a first side 110a″ (reference may be made to FIG. 1C and FIG. 1D), and the surface roughness Ra of the first side 110a″ is less than 0.5 nm.

Finally, referring to FIG. 1D and Step S4 in FIG. 2, the semiconductor wafer 110″ is flipped so that the unpolished second side 110b′ faces the polishing pad 320, and a second single-sided polishing process is performed on the second side 110b′.

In some embodiments, the thickness of the semiconductor wafer 110″ is reduced by 1 μm to 2 μm in the second single-sided polishing process. In some embodiments, the surface roughness Ra of the second side 110b′ of the semiconductor wafer 110″ after the second single-sided polishing process is less than 0.5 nm. In some embodiments, the total thickness loss of the semiconductor wafer in the first single-sided polishing process and the second single-sided polishing process is about 2 μm to 5 μm.

In some embodiments, the total thickness variation (TTV) of the semiconductor wafer 110″ after the second single-sided polishing process is less than 2 μm, the BOW is +25 μm to −25 μm, and the WARP is +50 μm to −50 μm.

In some embodiments, the semiconductor wafer 110″ can be used as a seed crystal after undergoing the second single-sided polishing process, and can be used as a raw material for producing other semiconductor ingots. In some embodiments, the semiconductor wafer 110″ can be used as a raw material for manufacturing various chips after undergoing the second single-sided polishing process.

Some examples and comparative examples are provided below to better describe the disclosure. In the examples and comparative examples, the grinding wheel used may have a shape in which abrasive grains are embedded on the surface, and the size of the abrasive grains may be represented by mesh. Mesh is a measure of how many openings there are per inch in the sieve.

### Comparative Example 1

In Comparative Example 1, a semiconductor ingot is cut to obtain a semiconductor wafer. Next, a double-sided grinding process is performed on the first side and the second side of the semiconductor wafer. The double-sided grinding process includes 30 minutes of coarse grinding and 30 minutes of fine grinding. Coarse grinding is performed with a coarse grinding wheel ranging from 300 mesh to 800 mesh, while fine grinding is performed using a fine grinding wheel ranging from 1000 mesh to 10000 mesh. The thickness of the semiconductor wafer is reduced by 20 μm during the coarse grinding process and by 10 μm during the fine grinding process. After the grinding process, a single-sided polishing process is performed on the semiconductor wafer. The single-sided polishing process includes 120 minutes of rough polishing and 60 minutes of fine polishing. Rough polishing uses Al₂O₃ particles (or SiO₂ particles) with a particle size of 0.1 μm to 0.3 μm as abrasive grains, while fine polishing uses chemical polishing without using abrasive grains. The thickness of the semiconductor wafer is reduced by 1 μm to 2 μm in the rough polishing process, and is reduced by 0.1 μm to 0.5 μm in the fine polishing process. In Comparative Example 1, the time consumed by the grinding process plus the polishing process is at least 240 minutes.

### Comparative Example 2

In Comparative Example 2, a semiconductor ingot is cut to obtain a semiconductor wafer. Next, a double-sided grinding process is performed on the first side and the second side of the semiconductor wafer. The double-sided grinding process includes using diamond grinding fluid containing diamond particles with a median particle diameter (D50) of 4 μm to grind the semiconductor wafer for 10 minutes. During the grinding process, a load of 170 kg is applied to five eight-inch semiconductor wafers. The thickness of the semiconductor wafer is reduced by 30 μm during the grinding process. After the grinding process, a single-sided polishing process is performed on the semiconductor wafer. The single-sided polishing process includes 100 minutes of polishing. The thickness of the semiconductor wafer is reduced by 1 μm to 2 μm during the polishing process. In Comparative Example 2, the time consumed by the grinding process plus the polishing process is at least 110 minutes.

### Comparative Example 3

In Comparative Example 3, a semiconductor ingot is cut to obtain a semiconductor wafer. Next, a double-sided grinding process is performed on the first side and the second side of the semiconductor wafer. The double-sided grinding process includes using diamond grinding fluid containing diamond particles with a median particle diameter of 6 μm to grind the semiconductor wafer for 15 minutes. During the grinding process, a load of 170 kg is applied to five eight-inch semiconductor wafers. The thickness of the semiconductor wafer is reduced by 50 μm during the grinding process. After the grinding process, a single-sided polishing process is performed on the semiconductor wafer. The single-sided polishing process includes 100 minutes of polishing. The thickness of the semiconductor wafer is reduced by 1 μm to 2 μm during the polishing process. In Comparative Example 3, the time consumed by the grinding process plus the polishing process is at least 115 minutes.

### Example 1

In Example 1, a semiconductor ingot is cut to obtain a semiconductor wafer. Next, a double-sided grinding process is performed on the first side and the second side of the semiconductor wafer. The double-sided grinding process includes using diamond grinding fluid containing diamond particles with a median particle diameter of 3 μm to grind the semiconductor wafer for 20 minutes. During the grinding process, a load of 170 kg is applied to five eight-inch semiconductor wafers. The thickness of the semiconductor wafer is reduced by 28 μm during the grinding process. After the grinding process, a single-sided polishing process is performed on the semiconductor wafer. The single-sided polishing process includes 100 minutes of polishing. The thickness of the semiconductor wafer is reduced by 1 μm to 2 μm during the polishing process. In Example 1, the time consumed by the grinding process plus the polishing process is at least 120 minutes.

### Example 2

In Example 2, a semiconductor ingot is cut to obtain a semiconductor wafer. Next, a double-sided grinding process is performed on the first side and the second side of the semiconductor wafer. The double-sided grinding process includes using diamond grinding fluid containing diamond particles with a median particle diameter of 2 μm to grind the semiconductor wafer for 30 minutes. During the grinding process, a load of 170 kg is applied to five eight-inch semiconductor wafers. The thickness of the semiconductor wafer is reduced by 26 μm during the grinding process. After the grinding process, a single-sided polishing process is performed on the semiconductor wafer. The single-sided polishing process includes 100 minutes of polishing. The thickness of the semiconductor wafer is reduced by 1 μm to 2 μm during the polishing process. In Example 2, the time consumed by the grinding process plus the polishing process is at least 115 minutes.

### Example 3

In Example 3, a semiconductor ingot is cut to obtain a semiconductor wafer. Next, a double-sided grinding process is performed on the first side and the second side of the semiconductor wafer. The double-sided grinding process includes using diamond grinding fluid containing diamond particles with a median particle diameter of 1 μm to grind the semiconductor wafer for 30 minutes. During the grinding process, a load of 170 kg is applied to five eight-inch semiconductor wafers. The thickness of the semiconductor wafer is reduced by 24 μm during the grinding process. After the grinding process, a single-sided polishing process is performed on the semiconductor wafer. The single-sided polishing process includes 100 minutes of polishing. The thickness of the semiconductor wafer is reduced by 1 μm to 2 μm during the polishing process. In Example 3, the time consumed by the grinding process plus the polishing process is at least 115 minutes.

### Example 4

In Example 4, a semiconductor ingot is cut to obtain a semiconductor wafer. Next, a double-sided grinding process is performed on the first side and the second side of the semiconductor wafer. The double-sided grinding process includes using diamond grinding fluid containing diamond particles with a median particle diameter of 0.1 μm to grind the semiconductor wafer for 30 minutes. During the grinding process, a load of 170 kg is applied to five eight-inch semiconductor wafers. The thickness of the semiconductor wafer is reduced by 20 μm during the grinding process. After the grinding process, a single-sided polishing process is performed on the semiconductor wafer. The single-sided polishing process includes 100 minutes of polishing. The thickness of the semiconductor wafer is reduced by 1 μm to 2 μm during the polishing process. In Example 4, the time consumed by the grinding process plus the polishing process is at least 115 minutes.

Table 1 shows geometric representations of the semiconductor wafers obtained from the processing processes of Comparative Example 1 to Comparative Example 3 and Example 1 to Example 4.

TABLE 1

| | | | | Thickness | | |
|---|---|---|---|---|---|---|
| | | Thickness | | removed by | | |
| | | removed by | | polishing | Processing | Geometric |
| | Grinding process | grinding process | Polishing process | process | time | representation |
| Comparative | Coarse grinding + | Coarse grinding | Rough polishing + | Rough polishing | 240 min | TTV: 2.5 μm |
| Example 1 | fine grinding | 20 μm | fine polishing | 1 to 2 μm | | BOW: 30 μm |
| | | fine grinding | | fine polishing | | WARP: ±60 μm |
| | | 10 μm | | 0.1 to 0.5 μm | | Ra: 0.8 nm |
| Comparative | Diamond particle of | 30 μm | Polishing | 1 to 2 μm | 110 min | TTV: 3 μm |
| Example 2 | D50 = 4 μm | | | | | BOW: 35 μm |
| | | | | | | WARP: ±60 μm |
| | | | | | | Ra: 0.8 nm |
| Comparative | Diamond particle of | 50 μm | Polishing | 1 to 2 μm | 115 min | TTV: 5 μm |
| Example 3 | D50 = 6 μm | | | | | BOW: 40 μm |
| | | | | | | WARP: ±70 μm |
| | | | | | | Ra: 1 nm |
| Example 1 | Diamond particle of | 28 μm | Polishing | 1 to 2 μm | 120 min | TTV: 2 μm |
| | D50 = 3 μm | | | | | BOW: 25 μm |
| | | | | | | WARP: ±55 μm |
| | | | | | | Ra: 0.5 nm |
| Example 2 | Diamond particle of | 26 μm | Polishing | 1 to 2 μm | 115 min | TTV: 2 μm |
| | D50 = 2 μm | | | | | BOW: 20 μm |
| | | | | | | WARP: ±50 μm |
| | | | | | | Ra: 0.4 nm |
| Example 3 | Diamond particle of | 24 μm | Polishing | 1 to 2 μm | 115 min | TTV: 2 μm |
| | D50 = 1 μm | | | | | BOW: 25 μm |
| | | | | | | WARP: ±55 μm |
| | | | | | | Ra: 0.3 nm |
| Example 4 | Diamond particle of | 20 μm | Polishing | 1 to 2 μm | 115 min | TTV: 2 μm |
| | D50 = 0.1 μm | | | | | BOW: 25 μm |
| | | | | | | WARP: ±55 μm |
| | | | | | | Ra: 0.1 nm |

It may be seen from Table 1 that using diamond grinding fluid containing diamond particles to perform the grinding process can greatly shorten the processing time. In addition, when the median particle diameter of the diamond particles in the diamond grinding fluid is less than or equal to 3 μm, the geometric representations of the semiconductor wafers after the processing processes can be significantly improved.

What is claimed is:

1. A semiconductor processing method, comprising:
cutting a semiconductor ingot to obtain a semiconductor wafer, wherein the semiconductor wafer comprises a first side and a second side opposite to the first side; and
performing a double-sided grinding process to simultaneously grind the first side and the second side of the semiconductor wafer using diamond grinding fluid, wherein the diamond grinding fluid comprises diamond particles with a median particle diameter of 0.1 μm to 3 μm.

2. The processing method as claimed in claim 1, wherein one or more semiconductor ingots are cut to obtain a plurality of semiconductor wafers, 1 to 10 among the plurality of semiconductor wafers are placed in a first carrier, the double-sided grinding process is simultaneously performed on the 1 to 10 among the plurality of semiconductor wafers in the first carrier, and in response to performing the double-sided grinding process, a load is applied to the 1 to 10 among the plurality of semiconductor wafers in the first carrier.

3. The processing method as claimed in claim 1, wherein a thickness of the semiconductor wafer is reduced by 20 μm to 28 μm in the double-sided grinding process.

4. The processing method as claimed in claim 1, further comprising:
performing a first single-sided polishing process on the first side after the double-sided grinding process.

5. The processing method as claimed in claim 4, wherein a thickness of the semiconductor wafer is reduced by 1 μm to 2 μm in the first single-sided polishing process.

6. The processing method as claimed in claim 4, further comprising:
performing a second single-sided polishing process on the second side after the first single-sided polishing process.

7. The processing method as claimed in claim 6, wherein a thickness of the semiconductor wafer is reduced by 1 μm to 2 μm in the second single-sided polishing process.

8. The processing method as claimed in claim 6, wherein a total thickness variation of the semiconductor wafer after the second single-sided polishing process is less than 2 μm.

9. The processing method as claimed in claim 6, wherein a BOW of the semiconductor wafer after the second single-sided polishing process is +25 μm to −25 μm, and a WARP is +50 μm to −50 μm.

10. The processing method as claimed in claim 4, wherein after the first single-sided polishing process, a surface roughness Ra of the first side is less than 0.5 nm.
